(19) United States
(12) Patent Application Publication
(10) Pub. No.: US 2025/0140591 A1
(43) Pub. Date: May 1, 2025

(54) Method for Controlling Substrate Processing System and Substrate Processing System

(71) Applicant: Tokyo Electron Limited, Tokyo (JP)

(72) Inventor: Toshiaki KODAMA, Yamanashi (JP)

(21) Appl. No.: 18/921,771

(22) Filed: Oct. 21, 2024

(30) Foreign Application Priority Data
Oct. 31, 2023 (JP) 2023-186352

(51) Int. Cl. H01L 21/68; G05B 19/418; H01L 21/687

(52) U.S. Cl. CPC H01L 21/68; G05B 19/4189; H01L 21/68707; G05B 2219/45049

(57) ABSTRACT

Provided is a method for controlling a substrate processing system comprising: detecting a distance between the first fork and the placing table by a distance sensor provided at the first fork; adjusting a height position of the first fork based on the detection value of the distance sensor; setting the adjusted height position of the first fork as a transfer height of the first fork; detecting a first touch position where lift pins of the placing table are brought into contact with the first object; unloading the first fork holding the first object; detecting a second touch position where the lift pins of the placing table are brought into contact with the second object; setting a transfer height of the second fork based on a difference between the first touch position and the second touch position; and unloading the second fork holding the second object.

### CROSS-REFERENCE TO RELATED APPLICATIONS

This application claims priority to Japanese Patent Application No. 2023-186352 filed on Oct. 31, 2023, the entire contents of which are incorporated herein by reference.

### TECHNICAL FIELD

The present disclosure relates to a method for controlling a substrate processing system and a substrate processing system.

### BACKGROUND

Japanese Laid-open Patent Publication No. 2022-132087 discloses a substrate processing system (transfer system) for transferring a substrate, which is an object to be transferred, using a vacuum transfer robot (transfer device) of a vacuum transfer module, and processing the substrate in a processing module.

In the substrate processing system, a central position of a placing location (e.g., a placing table of a processing module or the like) where the substrate is received and delivered is taught to the transfer device during setting or maintenance. Accordingly, the substrate processing system can accurately move the transfer device based on the taught positions during an operation of actually transferring the substrate and processing the substrate.

### SUMMARY

The present disclosure provides a technique that provides a substrate processing system for precisely controlling a height of a fork of a transfer device and a method for controlling a substrate processing system.

In accordance with an aspect of the present disclosure, there is provided a method for controlling a substrate processing system including a module having a placing table, a transfer module, and a transfer device disposed at the transfer module and having a first fork and a second fork, the method comprising: loading the first fork holding a first object to be transferred into the module and placing the first fork above the placing table; detecting a distance between the first fork and the placing table by a distance sensor provided at the first fork; adjusting a height position of the first fork based on the detection value of the distance sensor; setting the adjusted height position of the first fork as a transfer height of the first fork; detecting a first touch position where lift pins of the placing table are brought into contact with the first object to be transferred; unloading the first fork holding the first object to be transferred from the module; loading the second fork holding a second object to be transferred into the module and placing the second fork on the placing table; detecting a second touch position where the lift pins of the placing table are brought into contact with the second object to be transferred; setting a transfer height of the second fork based on a difference between the first touch position and the second touch position; and unloading the second fork holding the second object to be transferred from the module.

### BRIEF DESCRIPTION OF THE DRAWINGS

FIG. 1 shows an example of a schematic plan view showing an example of an overall configuration of a substrate processing system 1 according to an embodiment.

FIG. 2 shows an example of an enlarged plan view of a substrate and one fork of a vacuum transfer device.

FIG. 3 shows an example of a flowchart showing a method for teaching a height of a fork.

FIGS. 4A to 4C show an example of a schematic cross-sectional view showing a state of a substrate, a fork, and a placing table in each step.

FIGS. 5A to 5D show an example of a schematic cross-sectional view showing the state of the substrate, the fork, and the placing table in each step.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

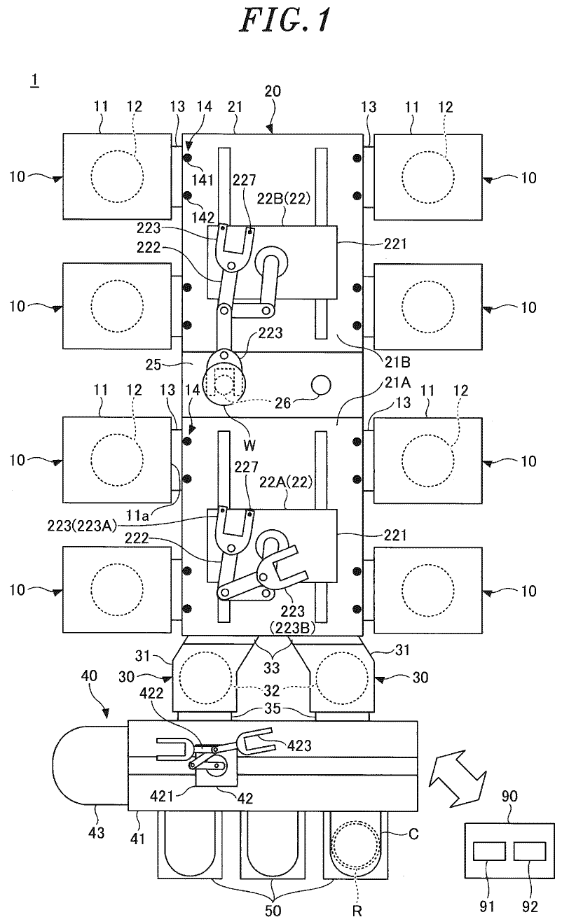

FIG. 1 is an example of a schematic plan view showing an example of an overall configuration of a substrate processing system 1 according to an embodiment. As shown in FIG. 1, the substrate processing system 1 is a multi-chamber type semiconductor manufacturing apparatus including a plurality of processing modules 10. Each processing module 10 performs substrate processing such as film formation, etching, cleaning, or the like on a substrate W that is an example of an object to be transferred. The substrate processing system 1 further include, in addition to the processing modules 10, a vacuum transfer module (transfer module) 20, a plurality of load-lock modules 30, an atmospheric transfer module (transfer module) 40, load ports 50, and a controller 90.

The substrate is loaded and unloaded between tach processing module 10 and the vacuum transfer module 20. Each processing module 10 performs substrate processing on the substrate W accommodated therein. Further, the processing modules 10 of the substrate processing system 1 may perform the same processing. Alternatively, some of them or all of them may perform different types of processing. The substrate processing system 1 may be configured to perform plasma processing in some or all of the processing modules 10.

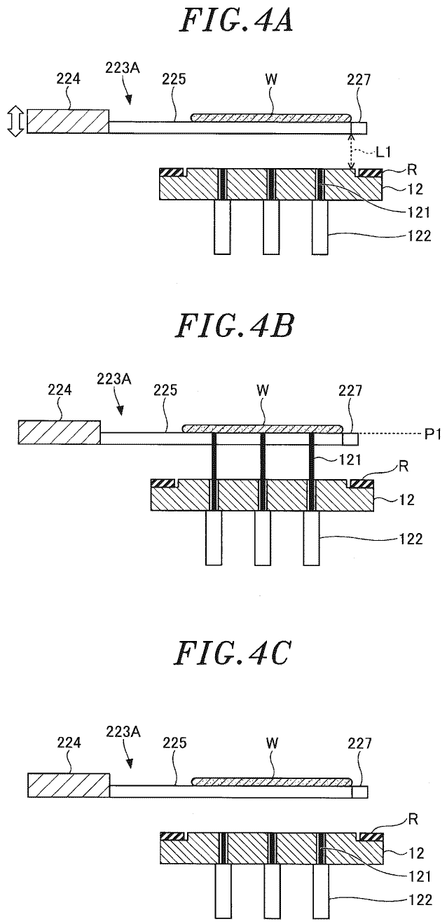

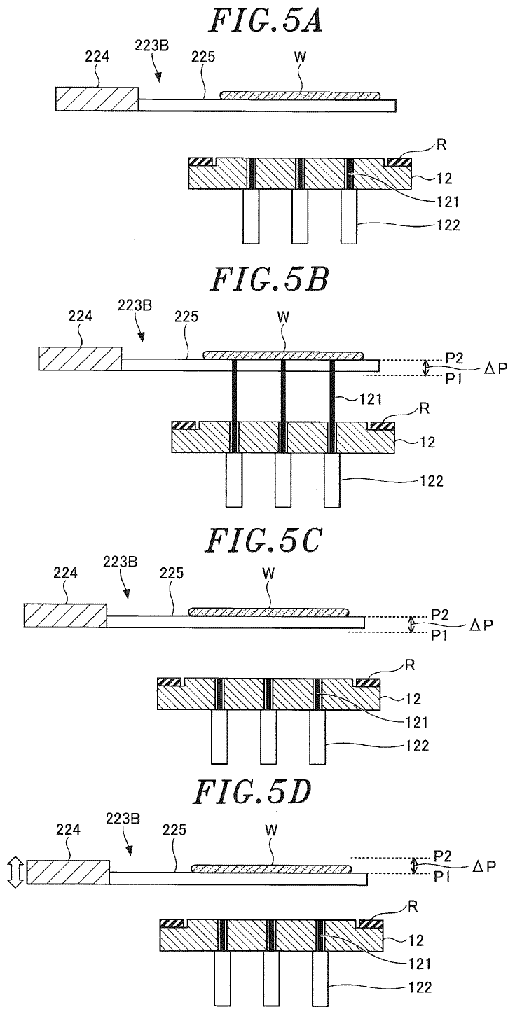

Specifically, each processing module 10 includes a processing chamber 11 accommodating a substrate W, and a placing table 12 on which the substrate W is placed in the processing chamber 11. The placing table 12 is provided with a plurality of lift pins 121 (see FIGS. 4 and 5 to be described later) for raising and lowering the substrate W, and receives and transfers the substrate W in cooperation with a vacuum transfer device 22 to be described later.

Further, each processing module 10 includes a connection part 13 that connects the processing chamber 11 and the vacuum transfer module 20, and a processing module-side sensor 14 that detects the substrate W. The connection part 13 has therein a gate valve (not shown) that opens and closes the opening 11a of the processing chamber 11. In each processing module 10, the substrate W can be transferred to the processing chamber 11 via the connection part 13 by opening the gate valve, and the pressure in the processing chamber 11 can be reduced to an appropriate vacuum atmosphere by closing the gate valve.

The processing module-side sensor 14 detects the outer edge of the substrate W when the substrate W is transferred between each processing module 10 and the vacuum transfer module 20, and transmits the detection information to the controller 90. The controller 90 can calculate the center position of the substrate W based on the detection information of the processing module-side sensor 14, and can also recognize the deviation of the center position of the substrate W that is being transferred to the vacuum transfer device 22. The processing module-side sensor 14 is disposed, e.g., at a position adjacent to the opening 11a of each processing module 10 in the vacuum transfer module 20. Further, the processing module-side sensor 14 may be provided inside the connection part 13 or may be provided at a position adjacent to the opening 11a in the processing module 10.

The processing module-side sensor 14 has two detectors 141 and 142 for detecting whether or not the substrate W exists. For example, each of the detectors 141 and 142 includes a light emitting part (not shown) for emitting measurement light, and a light receiving part (not shown) for receiving light from the light emitting part with a route through which the substrate W passes interposed therebetween. The detectors 141 and 142 detect the presence of the substrate W when the measurement light is blocked by the passage of the substrate W. The two detectors 141 and 142 are arranged in a direction parallel to the opening 11a, and they are disposed such that the distance therebetween becomes shorter than the diameter of the substrate W.

The vacuum transfer module 20 of the substrate processing system 1 is depressurized to a vacuum atmosphere. The vacuum transfer module 20 includes a transfer chamber 21 connected to the respective processing modules 10 and the plurality of load-lock modules 30, and a vacuum transfer device (transfer device) 22 that transfers the substrate W in the transfer chamber 21.

Further, in the vacuum transfer module 20 according to the embodiment, the inner space of the transfer chamber 21 is divided into three transfer regions along the longitudinal direction. Specifically, the vacuum transfer module 20 includes a front region 21A, a path region 25, and a rear region 21B in that order in a direction away from a position adjacent to the load-lock modules 30. However, the front region 21A, the path region 25, and the rear region 21B are not separated by partition walls or the like, and spatially communicate with each other in the transfer chamber 21.

The front region 21A is a first region of the vacuum transfer module 20 that transfers the substrate W between a plurality of (four in FIG. 1) processing modules 10, the path region 25, and the plurality of load-lock modules 30. A first transfer device 22A, which is a vacuum transfer device 22, is installed in the front region 21A. Further, the number of processing modules 10 connected to the front region 21A is not limited to four, and may be set to any number.

The rear region 21B is a second region of the vacuum transfer module 20 that transfers the substrate W between a plurality of (four in FIG. 1) processing modules 10 and the path region 25. A second transfer device 22B, which is a vacuum transfer device 22, is installed in the rear region 21B. Further, that the number of processing modules 10 connected to the rear region 21B is not limited to four, and may be set to any number. Further, the vacuum transfer device 22 does not necessarily include three transfer areas (the front region 21A, the path region 25, the rear region 21B), and may include four or more regions. For example, the vacuum transfer module 20 may include a transfer region having the vacuum transfer device 22 on one side (the upper side in FIG. 1) of the rear region 21B via another path region 25.

The path region 25 is a placing location prepared for receiving and transferring the substrate W between the first transfer device 22A in the front region 21A and the second transfer device 22B in the rear region 21B. Specifically, the path region 25 has a plurality of (two in FIG. 1) path placing parts 26 on which the substrate W is temporarily placed. When the substrate W held by the first transfer device 22A is placed on the path placing part 26 and the second transfer device 22B holds the substrate W on the path placing part 26, the transfer of the substrate W from the first transfer device 11A to the second transfer device 22B is completed. On the contrary, when the substrate W held by the second transfer device 22B is placed on the path placing part 26 and the first transfer device 22A holds the substrate W on the path placing part 26, the transfer of the substrate W from the second transfer device 22B to the first transfer device 22A is completed.

In the vacuum transfer module 20, two path placing parts 26 are arranged side by side in the lateral direction at an intermediate position in the longitudinal direction of the transfer chamber 21 to form the path region 25, thereby dividing the front region 21A and the rear region 21B. Further, in the vacuum transfer module 20, the location where the path placing parts 26 are disposed in the transfer chamber 21 may be simply set to the path region 25, but the path region 25 may be spatially partitioned from the front region 21A and the rear region 21B by a partition wall (not shown) or the like. In this case, an opening and a gate valve for opening and closing the opening are preferably formed in the partition wall. Further, the vacuum transfer module 20 may include a plurality of transfer regions by connecting the plurality of transfer chambers 21 (the transfer chamber having the front region 21A, the transfer chamber having the path region 25, and the transfer chamber having the rear region 21B).

The plurality of vacuum transfer devices 22 (the first transfer device 22A, and the second transfer device 22B) of the vacuum transfer module 20 are configured to operate independently. Each vacuum transfer device 22 has a base 221 that is movable in the longitudinal direction of the transfer chamber 21, a plurality of arms 222 that can rotate, extend and contract, and move up and down with respect to the base 221, and a fork (end effector) 223 (a first fork 223A and a second fork 223B) disposed at the arm 222 on the distal end side. Although FIG. 1 illustrates the vacuum transfer device 22 having two forks 223 (the first fork 223A and the second fork 223B), the vacuum transfer device 22 is not limited thereto, and may have a configuration including one or three or more forks 223. Among the multiple forks 223 (the first fork 223A and the second fork 223B) of the vacuum transfer device 22, one fork 223 (the first fork 223A) has fork-side sensors 227 to be described later, and the other fork 223 (the second fork 223B) does not have the fork-side sensors 227.

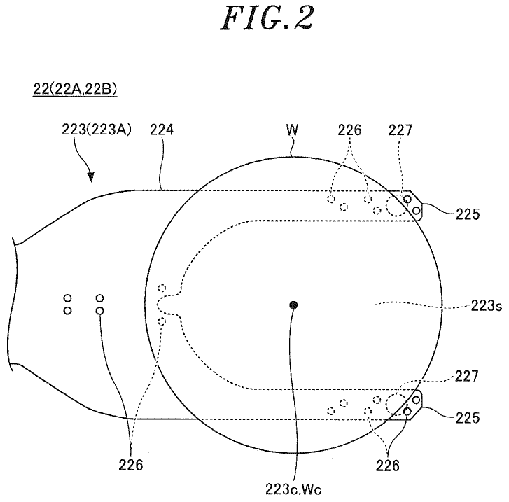

FIG. 2 is an example of an enlarged plan view showing the substrate W and one fork 223 (first fork 223A) of the vacuum transfer device 22. As shown in FIG. 2, the vacuum transfer device 22 supports the substrate W on the upper surface of the fork 223, and transfers the substrate W by appropriately operating the base 221 and the arms 222 (see FIG. 1). The other fork 223 (the second fork 223B) is different in that it does not include the fork-side sensors 227 to be described later. The other configurations are the same, and redundant description thereof will be omitted.

The fork 223 has a base plate portion 224 connected to the arm 222 on the distal end side, and a pair of support plate portions 225 extending while being branched from the base plate portion 224. The base plate portion 224 and the pair of support plate portions 225 are integrally molded with each other and continuous in the horizontal direction, thereby forming a U-shape in plan view. The pair of support plate portions 225 are parallel to each other, and have the same length. The fork 223 has a recessed space 223s surrounded by the base plate portion 224 and the pair of support plate portions 225. The recessed space 223s is open at the front end (extended end) of the pair of support plate portions 225.

The lift pins 121 (see FIGS. 4 and 5 to be described later) disposed at the placing table 12 are inserted through the recessed space 223s of the fork 223 configured as described above. Therefore, the fork 223 supporting the substrate W is placed directly above the placing table 12, and the lift pins 121 are raised to receive the substrate W. Then, the fork 223 retracts from the position above the placing table 12, and the lift pins 121 are lowered so that the substrate W can be placed on the upper surface of the placing table 12. Meanwhile, by raising the lift pins 121 in a state where the substrate W is supported on the upper surface of the placing table 12, the lift pins 121 support the substrate W. Then, an empty fork 223 is placed directly above the placing table 12 and below the substrate W supported by the lift pins 121, and the lift pins 121 are lowered to transfer the substrate W to the fork 223.

Further, the fork 223 has a plurality of pads 226 on the upper surfaces of the base plate portion 224 and the support plate portion 225. For example, the plurality of pads 226 are disposed at intermediate positions in the width direction of the base plate portion 224, and are also disposed on the tip end sides of the pair of support plate portions 225 to directly support the positions of the substrate W in three directions. The plurality of pads 226 may be made of a material (such as an elastomer or the like) having appropriate frictional force and elasticity. Further, the fork 223 may have a holding device such as a suction mechanism, an electrostatic attraction mechanism, or a mechanical locking mechanism for holding the substrate W using the plurality of pads 226 (or instead of the plurality of pads 226).

In the case of supporting the substrate W with the fork 223, the vacuum transfer device 22 moves the fork 223 such that a center position Wc of the substrate W coincides with a reference position 223c that is preset at the fork 223. Further, the position where the fork 223 of the vacuum transfer device 22 moves to support or place the substrate W corresponds to “transfer position” in the embodiment. The vacuum transfer device 22 can stably support the substrate W by moving the fork 223 such that the reference position 223c coincides with the transfer position and bringing the fork 223 into contact with the substrate W.

The fork 223 according to the embodiment has the plurality of (two in FIG. 2) fork-side sensors 227 for detecting the substrate Was an object to be transferred on the surface (bottom surface) opposite to the surface for supporting the substrate W. Specifically, the fork-side sensors 227 are disposed near the extension ends (tip ends of the fork 223) of the pair of support plate portions 225, and have detectors for detecting an object disposed below (opposed to) the fork 223 in the vertical direction. Each fork-side sensor 227 is connected to the controller 90 to be communicable therewith, performs detection under the control of the controller 90, and transmits the detection information to the controller 90.

For example, each fork-side sensor 227 according to the embodiment is a displacement sensor (optical displacement sensor) for optically measuring the distance from the fork 223 to the object. In this case, each fork-side sensor 227 has a light emitting part and a light receiving part included in a detector, and measures the distance to the object based on the light intensity or wavelength of the detection light emitted by the light emitting part and reflected by the object. Accordingly, the distance from the fork 223 to the placing table 12 is measured.

When the detection of the fork-side sensors 227 is continued while the fork 223 is moving above the substrate W, the fork-side sensors 227 can detect a change in the distance at the outer edge of the substrate W, and the controller 90 can recognize the outer edge of the substrate W based on the detection information. Further, the controller 90 can calculate the center position of the substrate W based on detection information at a plurality of locations on the outer edge of the substrate W.

Further, the type of the fork-side sensors 227 is not particularly limited as long as the distance from the fork 223 to the placing table 12 is measured. The fork-side sensor 227 may any one of an optical sensor, an image sensor, a distance sensor, a reflective light intensity sensor, an LED sensor, and the like.

Further, in the substrate processing system 1, the positions or numbers of the fork-side sensors 227 installed at the fork 223 is not particularly limited. As shown in FIG. 2, the fork-side sensors 227 may be provided at two locations on the tip end side of the support plate portion 225 while being spaced apart in the width direction of the fork 223. By providing the fork-side sensors 227 on the tip end side, sagging of the fork 223 can be preferably detected. Alternatively, the fork-side sensors 227 may be provided at four locations in the width direction and the longitudinal direction of the fork 223 while being spaced apart in the width direction and the longitudinal direction of the fork 223. Accordingly, the inclination of the fork 223 in the width direction or the longitudinal direction can be preferably detected.

Referring back to FIG. 1, the vacuum transfer device 22 (the first transfer device 22A and the second transfer device 22B) transfers the substrate W from an appropriate load-lock module 30 to an appropriate processing modules 10 under the control of the controller 90. Further, the vacuum transfer device 22 transfers the substrate W from an appropriate processing module 10 to an appropriate load-lock module 30 under the control of the controller 90. Further, the vacuum transfer device 22 may transfer the substrate W between two processing modules 10.

The two load-lock modules 30 of the substrate processing system 1 are disposed between the vacuum transfer module 20 and the atmospheric transfer module 40, and an inner atmosphere thereof is switched between an atmospheric atmosphere and a vacuum atmosphere. Specifically, each load-lock module 30 includes a chamber 31 accommodating a substrate W, and a placing table 32 for placing the substrate W thereon in the chamber 31. For example, the placing table 32 includes a groove (not shown) into which the fork 223 of the first transfer device 22A and a fork 423 of an atmospheric transfer device 42 (to be described later) can enter, and the substrate W is received and delivered by moving the forks 223 and 423 back and forth and up and down. Further, the placing table 32 may include lifters, similarly to the placing table 12 of the processing module 10.

Further, each load-lock module 30 has a connection part 33 on the vacuum transfer module 20 side and a connection part 35 on the atmospheric transfer module 40 side. The connection parts 33 and 35 have therein gate valves (not shown) for opening and closing the opening of the chamber 31. Each load-lock module 30 communicates with the vacuum transfer module 20 by opening the gate valve of the connection part 33 in a vacuum atmosphere state. Further, each load-lock module 30 communicates with the atmospheric transfer module 40 by opening the gate valve of the connection part 35 in an atmospheric atmosphere state.

The inner atmosphere of the atmospheric transfer module 40 of the substrate processing system 1 is maintained in an atmospheric atmosphere. The atmospheric transfer module 40 includes a transfer chamber 41 connected to the load-lock modules 30, and an atmospheric transfer device (transfer device) 42 for transferring the substrate W in the transfer chamber 41. Further, in the atmospheric transfer module 40, downflow of clean air may be generated in the transfer chamber 41. In addition, an aligner 43 for aligning the substrate W is disposed on the lateral side of the atmospheric transfer module 40.

Further, the plurality of load ports 50 are disposed on the wall surface of the atmospheric transfer module 40. A carrier C containing a substrate W or an empty carrier C is attached to each load port 50. For example, a front opening unified pod (FOUP) or the like may be used as the carrier C. Further, the carrier C accommodating a ring R (a focus ring, an edge ring, or the like) that is an example of an object to be transferred may be attached to each load port 50. The ring R is disposed around the substrate W on the placing table 12 of the processing module 10.

Similarly to the vacuum transfer device 22, the atmospheric transfer device 42 includes a base 421 that is movable in the longitudinal direction of the transfer chamber 41, a plurality of arms 422 that can rotate, extend and contract, and move up and down with respect to the base 421, and a fork (end effector) 423 disposed at the arm 422 on the distal end side. The atmospheric transfer device 42 supports the substrate W on the upper surface of the fork 423, and transfers the substrate W by appropriately operating the base 421 and the arms 422. Although FIG. 1 illustrates the atmospheric transfer device 42 including two forks 423, the present disclosure is not limited to thereto, and the atmospheric transfer device 42 may have a configuration including one or three or more forks 423.

The atmospheric transfer device 42 transfers the substrate W between each load-lock module 30 and the atmospheric transfer module 40 by opening and closing the gate valve of each connection part 35. Further, the atmospheric transfer device 42 transfers the substrate W between the aligner 43 and the atmospheric transfer module 40. Further, the atmospheric transfer device 42 transfers the substrate W between each carrier C attached to each load port 50 and the atmospheric transfer module 40.

The controller 90 is a computer having a processor 91, a memory 92, an input/output interface (not shown), and a communication interface (not shown). The processor 91 is combination of one or more of a central processing unit (CPU), a graphics processing unit (GPU), an application specific integrated circuit (ASIC), a field-programmable gate array (FPGA), a circuit including a plurality of discrete semiconductors, and the like, and executes the program stored in the memory 92. The memory 92 includes a main storage device such as a semiconductor memory, and an auxiliary storage device such as a disk or a semiconductor memory (flash memory).

For example, the controller 90 controls the atmospheric transfer device 42 to transfer an unprocessed substrate W of the carrier C attached to the load port 50 to the aligner 43 so that the substrate W can be aligned, and to transfer the substrate W of the aligner 43 to one of the load-lock modules 30. After the load-lock module 30 containing the substrate W is depressurized, the controller 90 controls the vacuum transfer device 22 to take out the substrate W and transfer the substrate W to one of the processing modules 10 via the vacuum transfer module 20. Then, the controller 90 performs substrate processing in each processing module 10 into which the substrate W is loaded. After the substrate processing, the controller 90 transfers the substrate W of one processing module 10 to the carrier C for accommodating a processed substrate W in a reverse order of the above-described sequence.

### <Teaching Method>

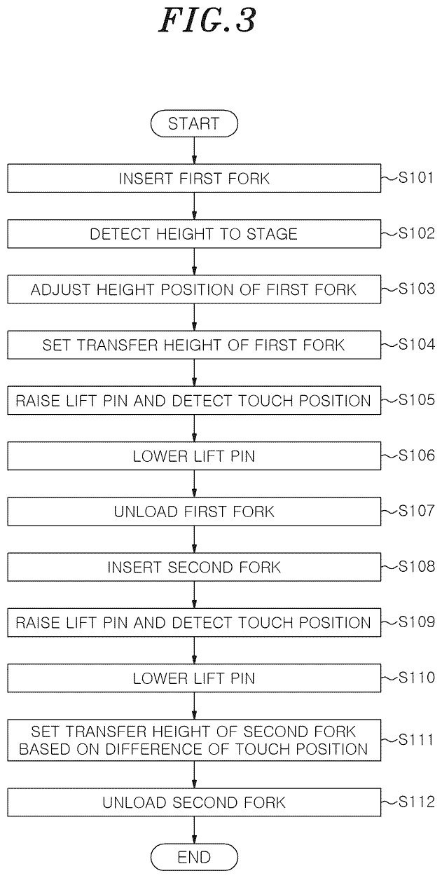

Next, a teaching method for a height of the forks 223 (the first fork 223A and the second fork 223B) in the vacuum transfer device 22 will be described with reference to FIGS. 3 to 5. FIG. 3 shows an example of a flowchart showing a teaching method for a height of the forks 223. FIGS. 4A-4C and 5A-5D show examples of schematic cross-sectional views showing the state of the substrate W, the forks 223, and the placing table 12 in each step. Here, a method for teaching the height position of the forks 223 (the first fork 223A and the second fork 223B) during an operation of inserting the forks 223 into the processing chamber 11 will be described. In the following description, one horizontal direction is defined as the X-axis, the other horizontal direction perpendicular to the X-axis is defined as the Y-axis, and the vertical direction is defined as the Z-axis.

In step S101, the first fork 223A is inserted into the processing chamber 11. Here, the controller 90 controls the vacuum transfer device 22 to insert the first fork 223A holding the substrate W (object to be transferred) into the processing chamber 11, and to place the first fork 223A holding the substrate W on the placing table 12.

Here, the vacuum transfer device 22 has a lifting mechanism (not shown) for raising and lowering the arm 222 with respect to the base 221. The controller 90 controls the height position (position in the Z-axis direction) of the fork 223 by controlling the lifting mechanism to raise and lower the arm 222. Further, the controller 90 controls the horizontal position (positions in the X-axis direction and the Y-axis direction) of the fork 223 by controlling the movement of the base 221 and the angle of each joint of the arm 222.

The controller 90 controls the positions in the X-axis direction and the Y-axis direction of the first fork 223A such that the center position Wc of the substrate W coincides with the center of the placing table 12 in plan view. The lifting amount of the lifting mechanism of the vacuum transfer device 22 is controlled to a predetermined initial value.

In step S102, the height to the stage (placing table 12) is detected. Here, the controller 90 uses the fork-side sensors 227 to detect the height (distance) from the placing table 12 to the first fork 223A.

In step S103, the height position of the first fork 223A is adjusted. FIG. 4A shows an example of a schematic cross-sectional view showing the state of the substrate W, the fork 223, and the placing table 12 in step S103. Here, the controller 90 controls the lifting mechanism of the vacuum transfer device 22 such that the height from the placing table 12 to the first fork 223A becomes a desired distance L1. Specifically, the lifting amount of the lifting mechanism of the vacuum transfer device 22 is corrected from the initial value of step S101 based on the difference between the height (distance) from the placing table 12 to the first fork 223A detected in step S102 and the desired distance L1. In other words, the lifting amount of the lifting mechanism of the vacuum transfer device 22 is adjusted such that the difference between the height (distance) detected in step S102 and the desired distance L1 becomes zero. Accordingly, the distance from the placing table 12 to the first fork 223A becomes the desired distance L1.

Further, the processes of steps S102 to S103 may be repeated until the difference between the height (distance) detected in step S102 and the desired distance L1 becomes sufficiently close to zero (i.e., until the difference becomes less than a predetermined threshold).

In step S104, the transfer height of the first fork 223A is set. Here, the controller 90 sets (teaches) the lifting amount of the lifting mechanism that has been adjusted such that the height from the placing table 12 to the first fork 223A becomes the desired distance L1 as the transfer height of the first fork 223A, and stores it in the memory 92.

In step S105, the lift pins 121 are raised, and a touch position where the lift pins 121 are brought into contact with the backside of the substrate W is detected. FIG. 4B shows an example of a schematic cross-sectional view showing the state of the substrate W, the forks 223, and the placing table 12 in step S105. Here, the controller 90 controls a driving part 122 to raise the lift pins 121. Here, the driving part 122 has a torque sensor. The lift pins 121 are raised to be in contact with the backside of the substrate W, and the substrate W is lifted by the lift pins 121, so that the torque for raising the lift pins 121 changes. Based on the change in torque during an operation of raising the lift pins 121, the controller 90 detects a lifting amount (first touch position) of the lift pins 121 when the lift pins 121 are brought into contact with the backside of the substrate W.

Further, based on the change in the motor current value of the driving part 122, the controller 90 may detect the lifting amount P1 (first touch position) of the lift pins 121 when the lift pins 121 are brought into contact with the backside of the substrate W.

Further, the method of detecting the touch position is not limited thereto. For example, in a configuration in which the forks 223 vacuum-attracts the substrate W, the substrate W is lifted by the lift pins 121 and separated from the forks 223, so that a suction pressure changes. Based on the change in the suction pressure, the controller 90 detects the lifting amount P1 (first touch position) of the lift pins 121 when they are brought into contact with the backside of the substrate W.

Further, in a configuration in which the forks 223 electrostatically attract the substrate W, the substrate W is lifted by the lift pins 121 and separated from the forks 223, so that a capacitance between the substrate W and the chuck electrode changes. Based on the change in the capacitance, the controller 90 detects the lifting amount P1 (first touch position) of the lift pins 121 when the lift pins 121 are brought into contact with the backside of the substrate W.

In step S106, the lift pins 121 are lowered. FIG. 4C shows an example of a schematic cross-sectional view showing the state of the substrate W, the forks 223, and the placing table 12 in step S106. Accordingly, the substrate W is supported by the first fork 223A. The lift pins 121 are accommodated in the placing table 12.

In step S107, the first fork 223A is unloaded from the processing chamber 11.

In step S108, the second fork 223B is inserted into the processing chamber 11. FIG. 5A shows an example of a schematic cross-sectional view showing the state of the substrate W, the fork 223, and the placing table 12 in step S108. Here, the controller 90 controls the vacuum transfer device 22 to insert the second fork 223B holding the substrate W (object to be transferred) into the processing chamber 11, and place the second fork 223B holding the substrate W on the placing table 12. The controller 90 controls the positions of the second fork 223B in the X-axis direction and the Y-axis direction such that the center position Wc of the substrate W coincides with the center of the placing table 12 in plan view. The lifting amount of the lift mechanism of the vacuum transfer device 22 is controlled to a predetermined initial value.

In step S109, the lift pins 121 are raised, and a touch position at which the lift pins 121 are brought into contact with the backside of the substrate W is detected. FIG. 5B shows an example of a schematic cross-sectional view showing the state of the substrate W, the fork 223, and the placing table 12 in step S109. Here, the controller 90 controls the driving part 122 to raise the lift pin 121. The controller 90 detects a lifting amount P2 (second touch position) of the lift pin 121 when the lift pins 121 are brought into contact with the backside of the substrate W based on the change in the torque during an operation of raising the lift pins 121. The method for detecting the touch position in step S109 is the same as the method for detecting the touch position in step S105, so that redundant description thereof will be omitted. Further, FIG. 5B shows the lifting amount P1 (first touch position) of the lifts pins 121 when the lift pins 121 are brought into contact with the backside of the substrate W in step S105. The difference (touch position difference) between the lifting amount P2 and the lifting amount P1 is defined as ΔP.

In step S110, the lift pins 121 are lowered. FIG. 5C shows an example of a schematic cross-sectional view showing the state of the substrate W, the fork 223, and the placing table 12 in step S110. Accordingly, the substrate W is supported by the second fork 223B. The lift pins 121 are accommodated in the placing table 12.

In step S111, the transfer height of the second fork 223B is set based on the difference of the touch positions. FIG. 5D shows an example of a schematic cross-sectional view showing the state of the substrate W, the fork 223, and the placing table 12 in step S111. Here, the controller 90 sets (teaches) the lifting amount of the lifting mechanism in which the height from the placing table 12 to the second fork 223B becomes the desired distance L1 as the transfer height of the second fork 223B, and stores it in the memory 92. Specifically, the controller 90 corrects the lifting amount of the lifting mechanism of the vacuum transfer device 22 from the initial value in step S108 based on the difference ΔP in the touch positions (the difference ΔP between the lifting amount P2 and the lifting amount P1). Further, the controller 90 sets (teaches) the lifting amount of the lifting mechanism corrected by the difference ΔP as the transfer height of the second fork 223B, and stores it in the memory 92.

In step S112, the second fork 223B is unloaded from the processing chamber 11.

Further, the processes from step S108 to step S112 may be repeated until the difference ΔP in the touch positions becomes sufficiently close to zero (i.e., until the difference ΔP becomes less than a predetermined threshold). When the processes from step S108 to step S112 is repeated, the lifting amount of the lifting mechanism of the vacuum transfer device 22 in step S108 may be the lifting amount corrected in the previous step S111.

As described above, in accordance with the teaching method shown in FIG. 3, the lifting amount (transfer height of the first fork 223A) of the lift mechanism of the vacuum transfer device 22 during an operation of inserting the first fork 223A into the processing chamber 11 can be set (taught). Accordingly, during an operation of inserting the first fork 223A into the processing chamber 11, the controller 90 controls the lifting amount of the vacuum transfer device 22 to the lifting amount stored (taught) in step S104. Hence, the height from the placing table 12 to the first fork 223A can be set to the desired distance L1 with high accuracy. Therefore, during an operation of inserting the first fork 223A into the processing chamber 11, it is possible to prevent the first fork 223A or the substrate W held by the first fork 223A from being in contact with other components in the processing chamber 11.

Further, in accordance with the teaching method shown in FIG. 3, the lifting amount (transfer height of the second fork 223B) of the lifting mechanism of the vacuum transfer device 22 during an operation of inserting the second fork 223B into the processing chamber 11 can be set (taught). Thus, during an operation off inserting the second fork 223B into the processing chamber 11, the controller 90 controls the lifting amount of the vacuum transfer device 22 to the lifting amount stored (taught) in step S111. Accordingly, the height from the placing table 12 to the second fork 223B can be set to the desired distance L1 with high accuracy. In other words, even in the case of the second fork 223B that does not have the fork-side sensors 227, the height (Z-axis direction) can be controlled with high accuracy. Hence, when the second fork 223B is inserted into the processing chamber 11, the second fork 223B and the substrate W held by the second fork 223B can be prevented from contacting other components in the processing chamber 11.

Further, by omitting the fork-side sensors 227 of the second fork 223B, the cost of the vacuum transfer device 22 can be reduced.

Further, in the vacuum transfer device 22 provided with three or more forks 223, at least one fork 223 may have the fork-side sensors 227, and the other forks 223 may not have the fork-side sensors 227. Further, the processes of steps S108 to S112 may be repeated for the forks 223 that do not have the fork-side sensors 227.

Further, the height position of the forks 223 (the first fork 223A and the second fork 223B) in the vacuum transfer device 22 can be taught while maintaining the vacuum atmosphere without opening the processing chamber 11 to the atmosphere. Accordingly, the downtime of the substrate processing system 1 can be reduced.

Further, in the flowchart shown in FIG. 3, the teaching method for the vacuum transfer device 22 has been described as an example. However, the present disclosure is not limited thereto, and the teaching method may be applied to failure prediction or abnormality detection of the vacuum transfer device 22. In the case of a certain fork 223, if the touch position difference due to the change over time (the difference between the touch position for inspection and the touch position for teaching) exceeds a predetermined first threshold, it may be determined that failure has been predicted. Further, in the case of a certain fork 223, if the touch position difference due to the change over time (the difference between the touch position for inspection and the touch position for teaching) exceeds a predetermined second threshold (second threshold>first threshold), it may be determined that abnormality has been detected. Further, if the touch position difference between one fork 223 and the other fork 223 exceeds a predetermined third threshold, it may be determined that failure has been predicted. If the touch position difference between one fork 223 and the other fork 223 exceeds a predetermined fourth threshold (fourth threshold>third threshold), it may be determined that abnormality has been detected. The failure prediction or the abnormality detection can be performed while maintaining the vacuum atmosphere without opening the processing chamber 11 to the atmosphere.

In the flowchart shown in FIG. 3, an example in which the vacuum transfer device 22 teaches the height position of the fork 223 during an operation of transferring the substrate W to the placing table 12 of the processing module 10 has been described. However, the present disclosure is not limited thereto, and can also be applied to a case where the vacuum transfer device 22 teaches the height position of the fork 223 during an operation of transferring the substrate W to the placing table of the module (e.g., the placing table 32 of the load-lock module 30). The present disclosure can also be applied to a case where the atmospheric transfer device 42 teaches the height position of the fork 423 during an operation of transferring the substrate W to the placing table of the module (e.g., the placing table 32 of the load-lock module 30).

The substrate processing system 1 and the transfer teaching method according to the embodiments of the present disclosure is illustrative in all respects and are not restrictive. The above-described embodiment may be changed or modified in various forms without departing from the scope of the appended claims and the gist thereof. The above-described embodiment may include other configurations without contradicting each other and may be combined without contradicting each other.

1. A method for controlling a substrate processing system including a module having a placing table, a transfer module, and a transfer device disposed at the transfer module and having a first fork and a second fork, the method comprising:
loading the first fork holding a first object to be transferred into the module and placing the first fork above the placing table;
detecting a distance between the first fork and the placing table by a distance sensor provided at the first fork;
adjusting a height position of the first fork based on the detection value of the distance sensor;
setting the adjusted height position of the first fork as a transfer height of the first fork;
detecting a first touch position where lift pins of the placing table are brought into contact with the first object to be transferred;
unloading the first fork holding the first object to be transferred from the module;
loading the second fork holding a second object to be transferred into the module and placing the second fork on the placing table;
detecting a second touch position where the lift pins of the placing table are brought into contact with the second object to be transferred;
setting a transfer height of the second fork based on a difference between the first touch position and the second touch position; and
unloading the second fork holding the second object to be transferred from the module.

2. The method for controlling a substrate processing system of claim 1, wherein the first fork has a base plate portion connected to an arm and a pair of support plate portions extending from the base plate portion, and
the distance sensor is disposed at the support plate portions.

3. The method for controlling a substrate processing system of claim 1, wherein the distance sensor is an optical displacement sensor.

4. The method for controlling a substrate processing system of claim 1, wherein the first touch position and/or the second touch position is detected based on a change in a torque of a driving part configured to drive the lift pins.

5. The method for controlling a substrate processing system of claim 1, wherein the first touch position and/or the second touch position is detected based on a change in a motor current value of the driving part configured to drive the lift pins.

6. The method for controlling a substrate processing system of claim 1, wherein the first touch position is detected based on a change in a chucking pressure that vacuum-attracts the first object to be transferred.

7. The method for controlling a substrate processing system of claim 1, wherein the second touch position is detected based on a change in a chucking pressure that vacuum-attracts the second object to be transferred.

8. The method for controlling a substrate processing system of claim 1, wherein the first touch position is detected based on a change in an electrostatic capacitance that electrostatically attracts the first object to be transferred.

9. The method for controlling a substrate processing system of claim 1, wherein the second touch position is detected based on a change in an electrostatic capacitance that electrostatically attracts the second object to be transferred.

10. A substrate processing system comprising:
a module having a placing table;
a transfer module;
a transfer device disposed at the transfer module and having a first fork and a second fork; and
a controller,
wherein the controller includes a processor and a memory contained instructions therein, the instructions when executed by the processor cause the processor to:
load the first fork holding a first object to be transferred into the module and placing the first fork on the placing table;
detect a distance between the first fork and the placing table using a distance sensor provided at the first fork;
adjust a height position of the first fork based on the detection value of the distance sensor;
set the adjusted height position of the first fork as a transfer height of the first fork;
detect a first touch position where lift pins of the placing table are in contact with the first object to be transferred;
transfer the first fork holding the first object to be transferred from the module;
transfer the second fork holding a second object to be transferred into the module and placing the second fork on the placing table;
detect a second touch position where the lift pins of the placing table contact the second object to be transferred;
set a transfer height of the second fork based on a difference between the first touch position and the second touch position; and
unload the second fork holding the second object to be transferred from the module.
